(19) United States
(12) Patent Application Publication
(10) Pub. No.: US 2026/0354126 A1
(43) Pub. Date: Nov. 5, 2026

(54) KNOWN-GOOD-DIE (KGD) APPROACH FOR SEMICONDUCTOR DIE TESTING

(71) Applicant: Taiwan Semiconductor Manufacturing Company, Ltd., Hsinchu (TW)

(72) Inventors: Shu-Cheng Chin, Hsinchu (TW); Kong-Beng Thei, Pao-Shan Village (TW)

(21) Appl. No.: 19/740,459

(22) Filed: Jul. 14, 2026

Related U.S. Application Data
(63) Continuation of application No. 18/926,369, filed on Oct. 25, 2024.

(51) Int. Cl. H10P 74/00; H10P 72/70; H10W 70/65

(52) U.S. Cl. CPC H10P 74/273; H10P 72/74; H10W 70/658

(57) ABSTRACT

Some embodiments relate to an integrated device, including: a substrate comprising a top surface; a semiconductor device on the substrate; an interconnect structure overlying the substrate and coupled to the semiconductor device; a first conductive pad coupled to the interconnect structure, wherein the first conductive pad has a first upper surface at a first height above the top surface of the substrate, and a second upper surface a second height above the top surface of the substrate, wherein the first height is greater than the second height.

### REFERENCE TO RELATED APPLICATION

This Application is a Continuation of U.S. Application number Ser. No. 18/926,369, filed on Oct. 25, 2024, the contents of which are hereby incorporated by reference in their entirety.

### BACKGROUND

The semiconductor industry has continually improved the processing capabilities and power consumption of integrated chips by shrinking the minimum feature size. Functional integrated chips may have a width of less than 10 micrometers. However, the testing of integrated chips has grown more difficult due to the reduction in feature size and the increased possibility of damaging smaller features.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A, 1B, 1C, 1D, and 1E illustrate cross-sectional views of some embodiments of an integrated circuit with conductive pads having upper surfaces with varying heights.

FIGS. 2A, 2B, 2C, and 2D illustrate top-down views of a redistribution layer in an intermediate step of the known-good-die (KGD) approach for testing a plurality of integrated circuits at once.

FIG. 3 illustrates a top down view of conductive pads of the plurality of integrated circuits shown in FIG. 2A after the testing.

FIG. 4 illustrates a cross-sectional view of some embodiments of an integrated circuit coupled to a second integrated circuit through the conductive pads.

FIG. 5 illustrates a cross-sectional view of some embodiments of vias coupled to the conductive pad of the integrated device.

FIG. 6 illustrates a top-down view of some embodiments of the conductive pad of the integrated device and a groove introduced during the patterning of the redistribution layer.

FIGS. 7-9, 10A-10B, 11-21 illustrate a series of cross-sectional views of some embodiments of a method of forming an integrated device utilizing the known-good-die (KGD) approach.

FIG. 22 illustrates a flowchart of some embodiments of a method of forming an integrated device utilizing the known-good-die (KGD) approach.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It will be appreciated that in this written description, as well as in the claims below, the terms “first”, “second”, “second”, “third” etc. are merely generic identifiers used for ease of description to distinguish between different elements of a figure or a series of figures. In and of themselves, these terms do not imply any temporal ordering or structural proximity for these elements, and are not intended to be descriptive of corresponding elements in different illustrated embodiments and/or un-illustrated embodiments. For example, “a first dielectric layer” described in connection with a first figure may not necessarily correspond to a “first dielectric layer” described in connection with another figure, and may not necessarily correspond to a “first dielectric layer” in an un-illustrated embodiment.

As integrated circuit technology has developed, various improvements to the compactness of circuits and features have been made. The decrease in size of the circuit components results in a reduction in the size of the resulting circuits and semiconductor dies being formed. Decreasing the size of the semiconductor die results in higher yields per wafer, improving the efficiency of the manufacturing process. However, testing the higher number of semiconductor dies grows more time consuming. Testing the individual semiconductor dies resulting from a single wafer may take days, significantly reducing the throughput of the manufacturing process. A method of testing multiple semiconductor dies at the same time is desirable to decrease the time taken on testing the integrated circuits formed, thereby increasing the efficiency of the manufacturing process.

The present disclosure provides a method of testing multiple semiconductor dies at a time. During the manufacturing process, circuit components and an interconnect structure for a plurality of semiconductor dies are formed over a substrate. The interconnect structure comprises a plurality of vias at the top surface of an interlayer dielectric. After the interconnect structure (and the surrounding interlayer dielectric) is formed, a redistribution layer is formed and patterned to couple the plurality of vias to a plurality of metal pads. The redistribution layer comprises a plurality of wires that couple corresponding vias (e.g., vias coupled to the same components of the semiconductor dies) of a portion of the semiconductor dies together, such that the portion of the semiconductor dies can be tested in parallel. An electrical test (e.g., a circuit probe test) is then performed on the semiconductor dies using the metal pads and the wires of the redistribution layer to determine if there are damaged or missing connections in any of the coupled semiconductor dies. If the test indicates a damaged connection or higher than expected voltage or current, the portion of the semiconductor dies is not used to form the final circuit. In this way, hundreds of semiconductor dies can be coupled together and tested at the same time, reducing the time to test a wafer of semiconductor dies from taking days to taking hours, greatly increasing the throughput of the manufacturing flow at the cost of additional semiconductor dies being discarded in the event of a failed test.

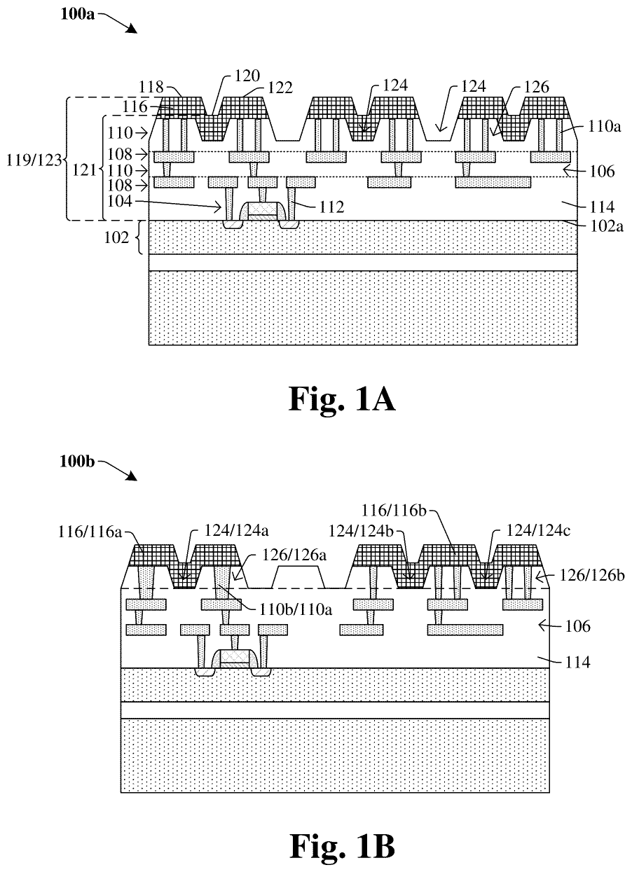

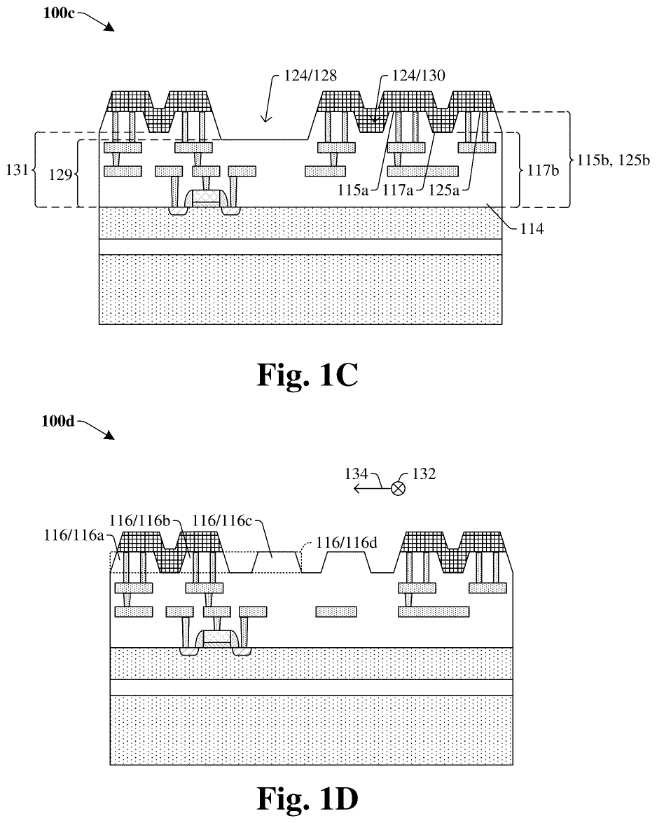

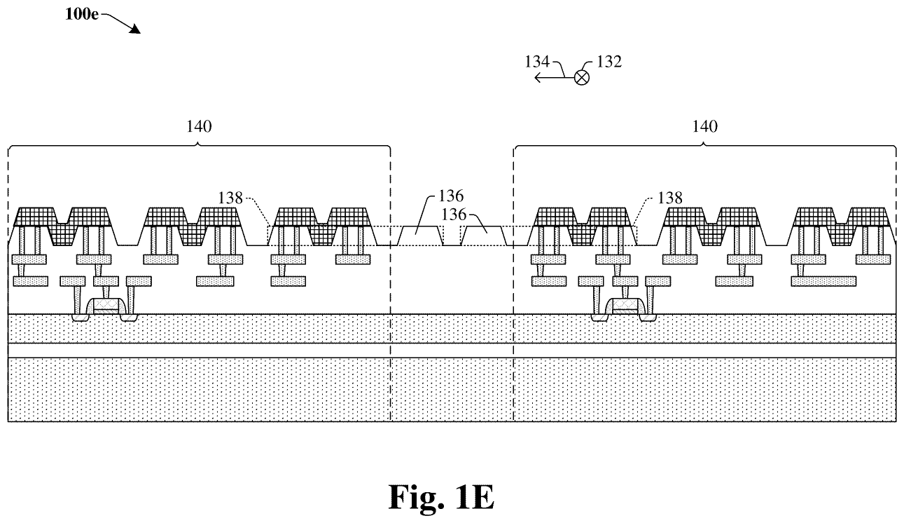

FIGS. 1A, 1B, 1C, 1D, and 1E illustrate cross-sectional views 100a, 100b, 100c, 100d, and 100e of some embodiments of an integrated circuit with conductive pads having upper surfaces with varying heights.

A plurality of semiconductor devices 104 are on a substrate 102. The plurality of semiconductor devices 104 comprises one or more of transistors (e.g., a planar FET, a FinFET, a gate-all-around (GAA) device, etc.), circuit components (e.g., resistors, capacitors, diodes, etc.), or the like. The plurality of semiconductor devices 104 are coupled to an interconnect structure 106. The interconnect structure 106 comprises a plurality of wire levels 108 and a plurality of via levels 110. In some embodiments, a plurality of contacts 112 couple the plurality of semiconductor devices 104 to the interconnect structure 106. The interconnect structure is surrounded by an interlayer dielectric 114. In some embodiments, the plurality of semiconductor devices 104 and the interconnect structure 106 are configured to form an light emitting diode (LED) driver circuit.

A plurality of conductive pads 116 are coupled to the interconnect structure through an uppermost via level of the plurality of via levels 110. In some embodiments, a portion of the plurality of conductive pads 116 are respectively coupled to the interconnect structure by four or more vias. The plurality of conductive pads 116 have a first upper surface 118 at a first height 119 above a top surface 102a of the substrate 102, a second upper surface 120 with a second height 121 above a top surface 102a of the substrate 102, and a third upper surface 122 with a third height 123 above a top surface 102a of the substrate 102. In some embodiments, the first height 119 and the third height 123 are substantially the same. The second height 121 is less than the first height 119 and the third height 123. In some embodiments, a conductive pad 116 is coupled to the interconnect structure 106 at a first lower surface directly beneath the first upper surface 118 and a second lower surface directly beneath the third upper surface 122.

The plurality of conductive pads 116 conform to the upper surface of the interlayer dielectric 114. Use of the known-good-die (KGD) approach to perform an electrical test (e.g., a probing test) on the integrated device (before the formation of the conductive pads) results in a plurality of grooves 124 extending between uppermost vias 110a and a plurality of protrusions 126 through which the uppermost vias 110a extend. The plurality of conductive pads 116 extend over and conform to a portion of the grooves 124, resulting in the plurality of conductive pads 116 having multiple upper surfaces (e.g., the first upper surface 118, the second upper surface 120, and the third upper surface 122) with varying heights.

As shown in the cross-sectional view 100b of FIG. 1B, in some embodiments, a first conductive pad 116a of the plurality of conductive pads 116 may conform to an upper surface of a first groove 124a of the plurality of grooves 124, and a second conductive pad 116b of the plurality of conductive pads 116 may conform to upper surfaces of a second groove 124b and a third groove 124c of the plurality of grooves 124. Conductive pads of the plurality of conductive pads 116 extend over and conform to the upper surfaces of any number of grooves 124 and protrusions 126 based on the design of the underlying semiconductor die. In some embodiments, the grooves 124 in the interlayer dielectric 114 delineate the plurality of protrusions 126 extending out of the interlayer dielectric 114 and comprising one or more uppermost vias 110a. For example, a single via 110b of the uppermost vias 110a may be in a first protrusion 126a, coupling the first conductive pad 116a to the interconnect structure 106, while multiple vias may be in a second protrusion 126b, coupling the second conductive pad 116b to the interconnect structure 106. In some embodiments, the uppermost vias 110a have a rectangular profile when viewed from a top-down view. In other embodiments, the uppermost vias 110a have a square or circular profile when viewed from a top-down view.

In some embodiments, the vias coupled to the plurality of conductive pads 116 couple individual conductive pads to multiple conductive paths within the interconnect structure 106. In this way, the plurality of conductive pads 116 may function as an additional wire layer, extending horizontally across the interconnect structure to couple conductive paths that otherwise were separated from one another by the interlayer dielectric 114. Further, in some embodiments, some protrusions 126 are not covered by a conductive pad of the plurality of conductive pads 116 and do not contain vias.

As shown in the cross-sectional view 100c of FIG. 1C, in some embodiments, a first portion 128 of the plurality of grooves 124 have a greater width than a second portion 130 of the plurality of grooves 124. In some embodiments, a portion of the plurality of grooves 124 extends from a first outer sidewall of the interlayer dielectric 114 to a second outer sidewall of the interlayer dielectric. That is, the portion of the plurality of grooves 124 extends across the semiconductor die. In further embodiments, a portion of the plurality of grooves extends partway across the semiconductor die, and extends to one outer sidewall of the semiconductor die without extending to a second outer sidewall of the semiconductor die. In some embodiments, the first portion 128 of the plurality of grooves 124 have bottom surfaces at a fourth height 129 above the substrate 102, and the second portion 130 of the plurality of grooves 124 have bottom surfaces a fifth height 131 above the substrate 102, wherein the fourth height 129 is less than the fifth height 131.

In some embodiments, the interlayer dielectric 114 surrounding the interconnect structure 106 comprises a first surface 115a at a sixth height 115b above the substrate, a second surface 117a at a seventh height 117b above the substrate, and a third surface 125a a eighth height 125b above a substrate 102, the seventh height 117b being less than the sixth height 115b and the eighth height 125b.

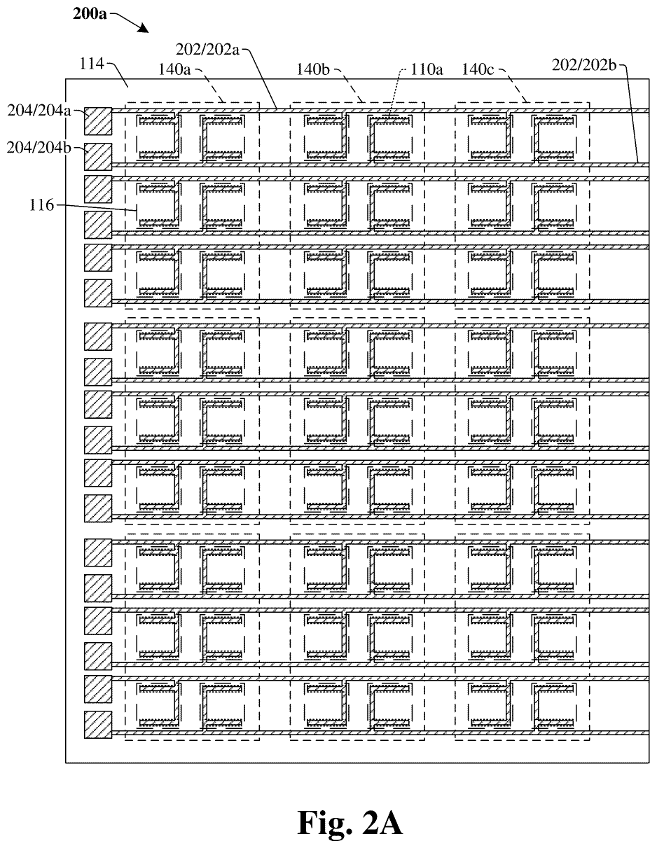

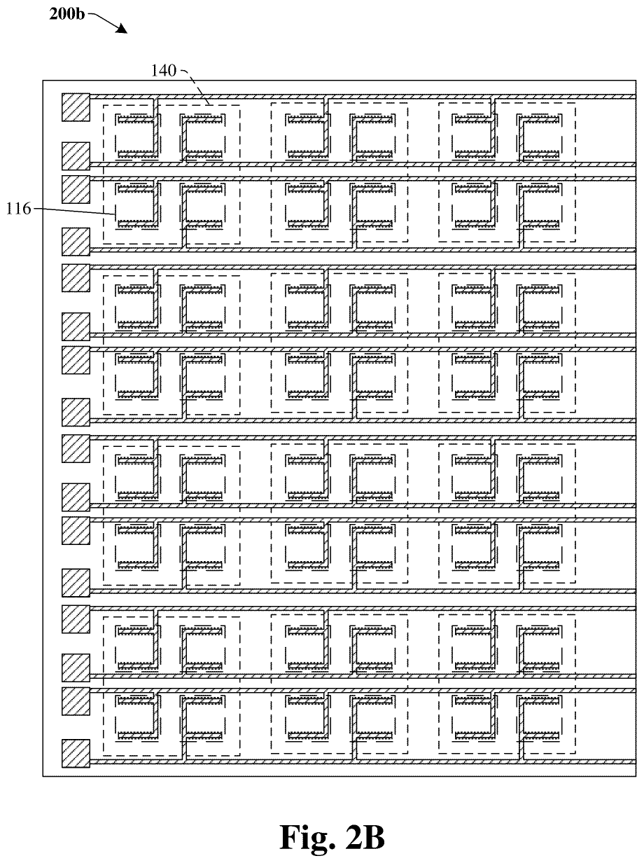

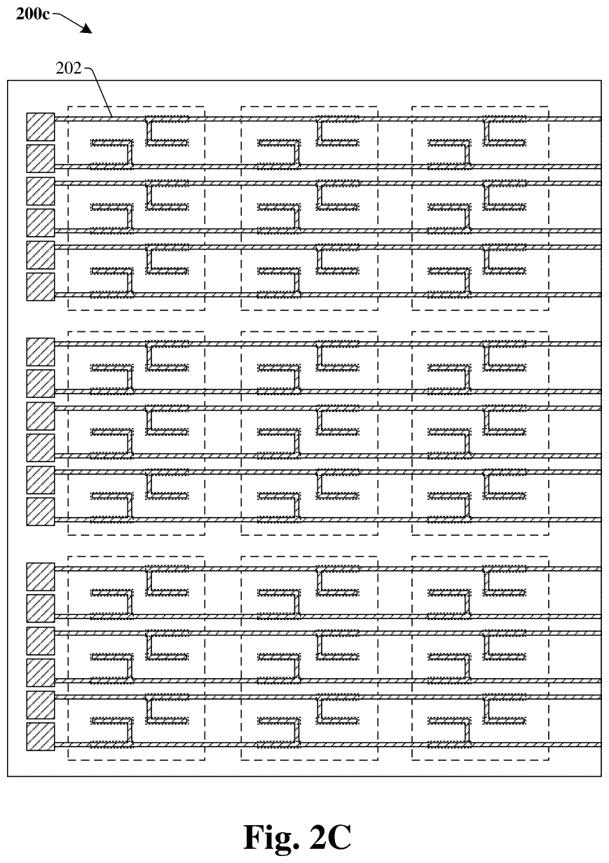

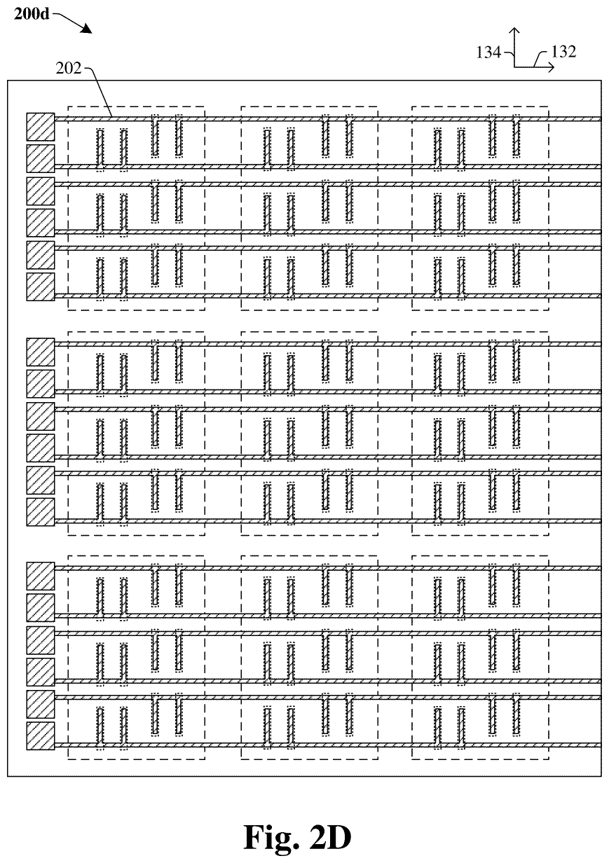

As shown in the cross-sectional view 100d of FIG. 1D, in some embodiments, multiple protrusions of the plurality of protrusions 126 extend between conductive pads of the plurality of conductive pads 116. In further embodiments, a first portion of the plurality of protrusions 126 are segments extending in a first direction 132, and a second portion of the plurality of protrusions 126 are segments extending in a second direction 134 perpendicular to the first direction 132. The second segments extend between the first segments, based on a pattern of a redistribution layer used for the probing test of the KGD approach (see FIGS. 2A, 2B, 2C, and 2D). For example, a first protrusion 126a and a second protrusion 126b extend parallel to a third protrusion 126c and are crossed by a fourth protrusion 126d (shown in phantom) extending perpendicular to the first protrusion 126a, the second protrusion 126b, and the third protrusion 126c.

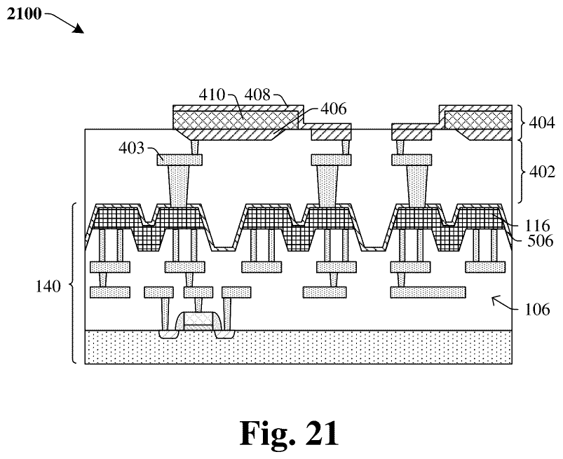

As shown in the cross-sectional view 110e of FIG. 1E, in some embodiments, in an intermediate step before the dicing of the semiconductor dies (see FIG. 21), additional protrusions 136 extend between the semiconductor dies. In some embodiments, the additional protrusions 136 extend past multiple semiconductor dies in the first direction 132 and there are perpendicular protrusions 138 (shown in phantom) that extend from the additional protrusions 136 to the semiconductor dies in the second direction 134.

FIGS. 2A, 2B, 2C, and 2D illustrate top-down views 200a, 200b, 200c, 200d of a redistribution layer in an intermediate step of the known-good-die (KGD) approach for testing a plurality of integrated circuits at once.

As shown in the top-down view 200a of FIG. 2A, in some embodiments, a redistribution layer (RDL) 202 is formed over the interlayer dielectric 114 before the plurality of conductive pads 116 (shown in phantom) are formed. The RDL 202 couples vias of a plurality of semiconductor dies to one another and to a plurality of metal pads 204. In some embodiments, the plurality of metal pads line one or more sides of the wafer and are each couples to over 100 semiconductor dies. The repeating pattern of the semiconductor dies results in the over 100 semiconductor dies being tested at the same time during the subsequent probing test. If one of the probing tests fails for a group of interconnected semiconductor dies (e.g., the voltage or current between two of the metal pads is higher or lower than expected), the semiconductor dies coupled to the metal pads 204 are discarded.

For example, first semiconductor die 140a, second semiconductor die 140b, and third semiconductor die 140c are directly beneath two wires of the RDL 202 and have uppermost vias 110a coupled to a first wire 202a and a second wire 202b of the RDL 202. When a first metal pad 204a coupled to the first wire 202a and a second metal pad 204b coupled to the second wire are probed, the voltage measured between the two pads is unexpectedly low. Therefore, one of the first semiconductor die 140a, the second semiconductor die 140b, the third semiconductor die 140c, or another semiconductor die 140 coupled to the first wire 202a and the second wire 202b may have a faulty circuit component or improper connection, resulting in the semiconductor dies coupled to the first wire 202a and the second wire 202b being discarded. While this does reduce the yield of the wafer being tested, the testing of hundreds of semiconductor dies at the same time reduces the testing time of the wafer, increasing the speed of the manufacturing process for the final chip.

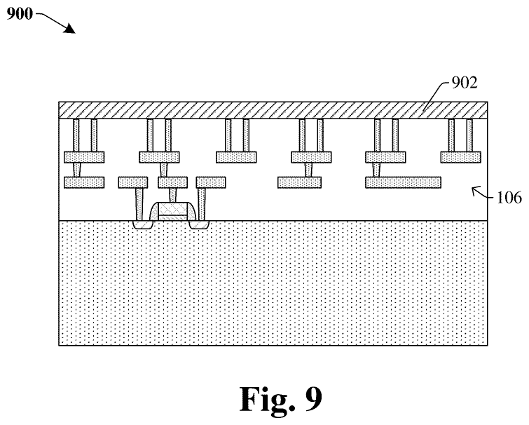

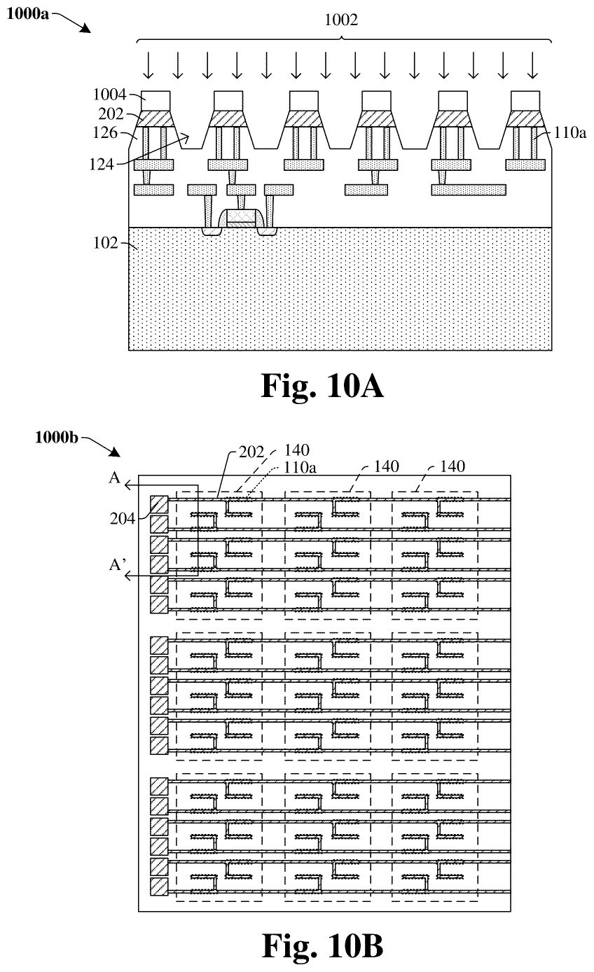

The RDL 202 is formed by depositing a conformal metal layer over the interlayer dielectric 114 and then patterning the conformal metal layer into the RDL 202 and the plurality of metal pads 204 (see FIGS. 9, 10A, and 10B). When the conformal metal layer is patterned, material of the interlayer dielectric 114 beneath the removed portions is also removed, resulting in the grooves 124 forming around the RDL 202. Therefore, the plurality of grooves 124 surrounding the vias in the uppermost level of the plurality of via levels 110 is indicative of the KGD approach being performed.

As shown in the top-down view 200b of FIG. 2B, in some embodiments, the number of conductive pads 116 (not yet formed in this figure) in each semiconductor die 140 may be more or less than six based on the function and design of the semiconductor die 140. For example, the number of conductive pads 116 in each semiconductor die 140 may be four, as shown. As shown in the top-down view 200c of FIG. 2C, the wires of the RDL 202 may follow different patterns to more effectively make use of the limited space available on the semiconductor dies and increase the space between the wires, further isolating the wires from one another. As shown in the top-down view 200d of FIG. 2D, the wires of the RDL 202 may run across the semiconductor dies 140 perpendicular to the direction of the uppermost vias 110a. For example, the wires of the RDL 202 extend in the first direction 132 whereas the uppermost vias 110a have a longest dimension extending in the second direction 134. It will be appreciated that other patterns of wires may be used to couple corresponding vias from different semiconductor dies to one wire of the RDL 202 and one metal pad of the plurality of metal pads 204.

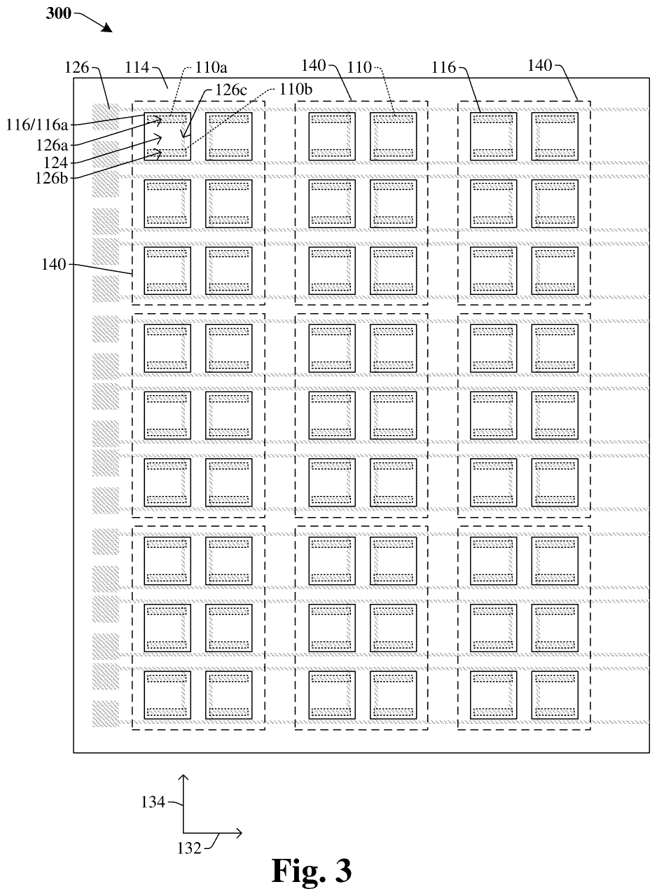

FIG. 3 illustrates a top down view 300 of conductive pads of the plurality of integrated circuits shown in FIG. 2A after the testing.

After the electrical test is performed, the RDL (see 202 of FIG. 2A) is removed and conductive pads 116 are formed over the uppermost vias 110a (shown in phantom). The grooves 124 and protrusions 126 resulting from the formation of the of the RDL 202 remain on the upper surfaces of the interlayer dielectric 114, resulting in the conductive pads 116 having multiple upper surfaces of varying heights. The protrusions 126 extend along the same path as the RDL (see 202 of FIG. 2A), and the grooves 124 extend between the protrusions 126. For example, a first set of vias 110c and a second set of vias 110d are directly beneath the first conductive pad 116a. A first protrusion segment 126a extends along the first set of vias 110c and a second protrusion segment 126b extends along the second set of vias 110d in the first direction 132. A third protrusion segment 126c extends between the first protrusion segment 126a and the second protrusion segment 126b in the second direction 134, resulting in the first, second, and third protrusion segments 126a, 126b, 126c forming a “U” shape. A groove of the plurality of grooves 124 extends between the first protrusion segment 126a and the second protrusion segment 126b, filling the “U” shape. Based on the pattern of the RDL (see 202 of FIG. 2A), the conductive pads 116 have protrusion segments extending in a “U” shape individual to them. In other embodiments with a different pattern of RDL (see 202 of FIG. 2A) or pattern of uppermost vias 110a, the protrusions extend over the semiconductor dies 140 in different patterns.

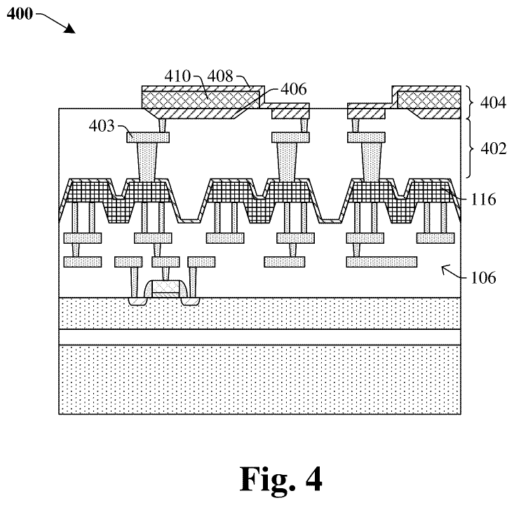

FIG. 4 illustrates a cross-sectional view 400 of some embodiments of an integrated circuit coupled to a second integrated circuit through the conductive pads.

In some embodiments, the plurality of conductive pads 116 couple the interconnect structure 106 to a second interconnect structure 402. In some embodiments, the second interconnect structure 402 is coupled to a plurality of micro-LEDs 404 disposed over the second interconnect structure 402, other suitable light emitting devices, or any combination of the foregoing. The second interconnect structure 402 is or comprises a redistribution layer 403 contacting the plurality of conductive pads 116. In some embodiments, one or more via layers extend between the redistribution layer 403 and the plurality of conductive pads 116. In other embodiments, the one or more via layers are omitted, and the redistribution layer 403 directly contacts the plurality of conductive pads 116.

In some embodiments, the plurality of micro-LEDs 404 are or comprise a first electrode 406, a second electrode 408, and a semiconductor layer 410 extending between the first electrode 406 and the second electrode 408. In some embodiments, the first electrode 406 and the second electrode 408 are formed separately from the redistribution layer 403. In other embodiments, the first electrode 406 and the second electrode 408 are portions of the redistribution layer 403.

In some embodiments, the first electrode 406 is or comprises a reflective conductive material, extends beneath the semiconductor layer 410, and functions as a reflector. In other embodiments, the first electrode 406 is or comprises a conductive material and/or does not function as a reflector. In some embodiments, the second electrode 408 overlies the semiconductor layer 410. In further embodiments, the second electrode 408 is or comprises a transparent conductive material, such as a transparent conducting oxide (TCO) (e.g., indium tin oxide (ITO). In other embodiments, the second electrode 408 does not overly the semiconductor layer 410 and/or comprises a conductive material, such as gold (Au), copper (Cu), titanium (Ti), titanium nitride (TiN), aluminum (Al), or the like. In some embodiments, the semiconductor layer 410 overlies the first electrode 406 and the second electrode 408. In other embodiments, the first electrode 406 is on a first side of the semiconductor layer 410 and the second electrode 408 is on a second side of the semiconductor layer 410 opposite the first side. The semiconductor layer 410 is configured to emit light when current passes between the first electrode 406 and the second electrode 408.

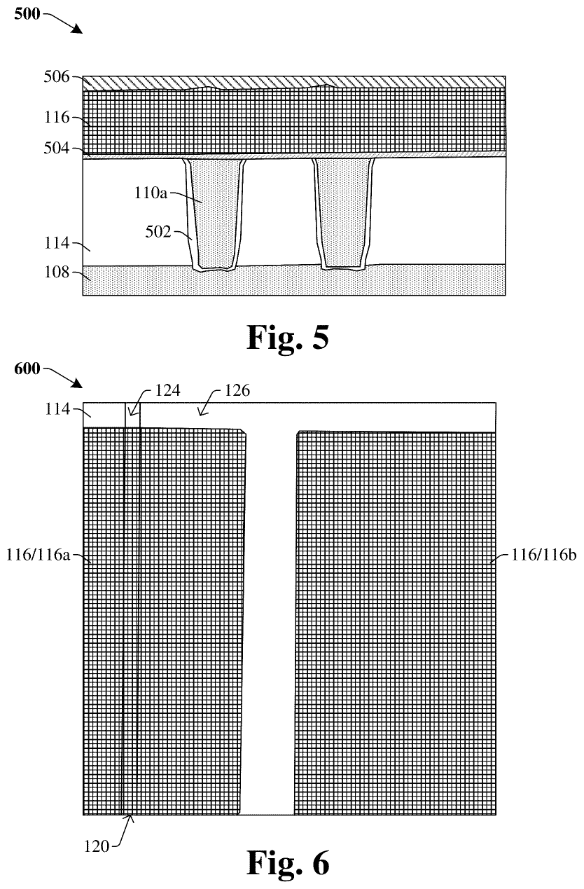

FIG. 5 illustrates a cross-sectional view 500 of some embodiments of vias coupled to the conductive pad of the integrated device.

In some embodiments, the uppermost vias 110a are surrounded by a first barrier layer 502. The first barrier layer 502 extends around a bottom and sidewalls of the vias. In some embodiments, the first barrier layer 502 has an uppermost surface substantially level with the uppermost surface of the vias. In some embodiments, the first barrier layer 502 is or comprises one or more of tantalum nitride (TaN), titanium nitride (TiN), nickel (Ni), or another, similar material. The first barrier layer 502 is configured to separate the vias from the interlayer dielectric 114, preventing the material of the vias from diffusing into the material of the interlayer dielectric 114.

In some embodiments, the plurality of conductive pads 116 are separated from the interlayer dielectric 114 by a second barrier layer 504. The second barrier layer 504 lines a bottom surface of the conductive pads 116. In some embodiments, the second barrier layer 504 is or comprises one or more of tantalum nitride (TaN), titanium nitride (TiN), nickel (Ni), or another, similar material. In some embodiments, the second barrier layer 504 is configured to adhere the plurality of conductive pads 116 to the interlayer dielectric 114 and the uppermost vias 110a.

In some embodiments, in an intermediate step, a third barrier layer 506 is formed over the conductive pads 116 and the interlayer dielectric to prevent damage to them during processes related to dicing the semiconductor die, transporting the semiconductor die, and adhering a carrier wafer to the substrate (see 102 of FIG. 1A) for transportation of the semiconductor die. In some embodiments, the third barrier layer 506 is or comprises one or more of aluminum oxide (Al₂O₃), hafnium oxide (HfO₂), titanium oxide (TiO₂), silicon nitride (Si₃N₄), titanium nitride (TiN), another similar material, or a combination thereof.

FIG. 6 illustrates a top-down view 600 of some embodiments of the conductive pad of the integrated device and a groove 124 introduced during the patterning of the redistribution layer. In some embodiments, the width of the protrusions 126 is greater than the width of the grooves 124. In further embodiments, the protrusions 126 extend to multiple adjacent conductive pads 116. For example, the protrusion 126 shown in FIG. 6 extends from a first conductive pad 116a to a second conductive pad 116b. In some embodiments, the second upper surface 120 of the first conductive pad 116a extends from a first outer sidewall of the first conductive pad 116a to a second outer sidewall of the first conductive pad 116a.

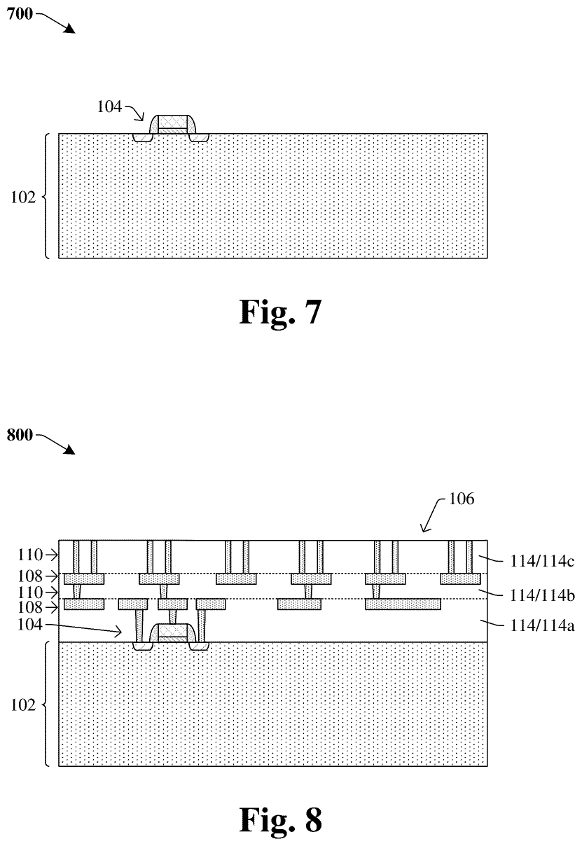

FIGS. 7-9, 10A-10B, and 11-21 illustrate a series of cross-sectional views of some embodiments of a method of forming an integrated device utilizing the known-good-die (KGD) approach. Although FIGS. 7-9, 10A-10B, and 11-21 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part. The cross-sectional view 1000a of FIG. 10A is taken along line A-A′ of the top-down view 1000b of FIG. 10B.

As shown in the cross-sectional view 700 of FIG. 7, a plurality of semiconductor devices 104 are formed on the substrate 102. The plurality of semiconductor devices 104 comprises one or more of transistors (e.g., a planar FET, a FinFET, a gate-all-around (GAA) device, etc.), circuit components (e.g., resistors, capacitors, diodes, etc.), or the like. Forming the plurality of semiconductor devices 104 comprises using one or more of physical vapor deposition (PVD), atomic layer deposition (ALD), chemical vapor deposition (CVD), etching, and implantation processes or the like to form the transistors and circuit components.

As shown in the cross-sectional view 800 of FIG. 8, in some embodiments, the interconnect structure 106 is formed over the plurality of semiconductor devices 104. The interconnect structure 106 comprises the plurality of wire levels 108, the plurality of via levels 110, and the plurality of contacts 112 coupling the interconnect structure 106 to the plurality of semiconductor devices 104. An interlayer dielectric 114 surrounds the plurality of wire levels 108 and the plurality of via levels 110. In some embodiments, the plurality of wire levels 108, the plurality of via levels 110, and the plurality of contacts 112 are or comprise one or more of aluminum (Al), copper (Cu), an aluminum copper alloy, tungsten (W), tantalum nitride (TaN), or the like. In some embodiments, the interlayer dielectric 114 is or comprises an insulative material such as one or more of silicon dioxide (SiO₂), silicon nitride (Si₃N₄), or the like.

In some embodiments, the interconnect structure 106 is formed by depositing a portion 114a of the interlayer dielectric 114, etching openings in the interlayer dielectric 114 corresponding to a wire level and via level, using one or more of PVD, ALD, CVD, or the like to form a metal layer filling the openings, and then removing a portion of the metal layer above the upper surface of the portion of the interlayer dielectric 114. This method is repeated for additional portions of the interlayer dielectric 114b, 114c until the interconnect structure 106 is complete. In some embodiments, the plurality of semiconductor devices 104 and the interconnect structure 106 are configured to form an LED driver circuit. In some embodiments, the uppermost via level of the plurality of via levels 110 is formed using a single damascene process.

As shown in the cross-sectional view 900 of FIG. 9, a first conformal metal layer 902 is formed over the interconnect structure 106. The first conformal metal layer 902 is or comprises one or more of aluminum (Al), gold (Au), titanium (Ti), ruthenium (Ru), iridium (Ir), rhodium (Rh), molybdenum (Mo), or the like. In some embodiments, the first conformal metal layer 902 is formed by using one or more of PVD, ALD, CVD, or the like.

As shown in the cross-sectional view 1000a of FIG. 10A and the top-down view 1000b of FIG. 10B, a first mask 1004 is formed over the substrate 102 and subsequently patterned. In some embodiments, the first mask 1004 comprises a photoresist and is patterned using photolithography. After the first mask 1004 is patterned, the first conformal metal layer (see 902 of FIG. 9) is patterned to form the RDL layer 202 and the plurality of metal pads 204. The pattern of the RDL layer 202 is configured to couple corresponding uppermost vias 110a in separate semiconductor dies to one another and to a metal pad of the plurality of metal pads 204.

In some embodiments, the patterning is performed using a dry etching process 1002. The dry etching process 1002 removes portions of the first conformal metal layer (see 902 of FIG. 9) that are not covered by the first mask 1004. Further, the interlayer dielectric 114 is partially etched away by the dry etching process 1002, resulting in the formation of the grooves 124 and the protrusions 126 across the upper surface of the interlayer dielectric 114. The first mask 1004 is subsequently removed.

After the removal of the first mask 1004, an electrical test is performed on the plurality of semiconductor dies 140. In some embodiments, the electrical test is performed by probing various metal pads 204 coupled to the plurality of semiconductor dies 140 and measuring the resulting voltage and current between the probed metal pads 204. The resulting measurements are used to determine which semiconductor dies are to be kept after the dicing process and used in the final product.

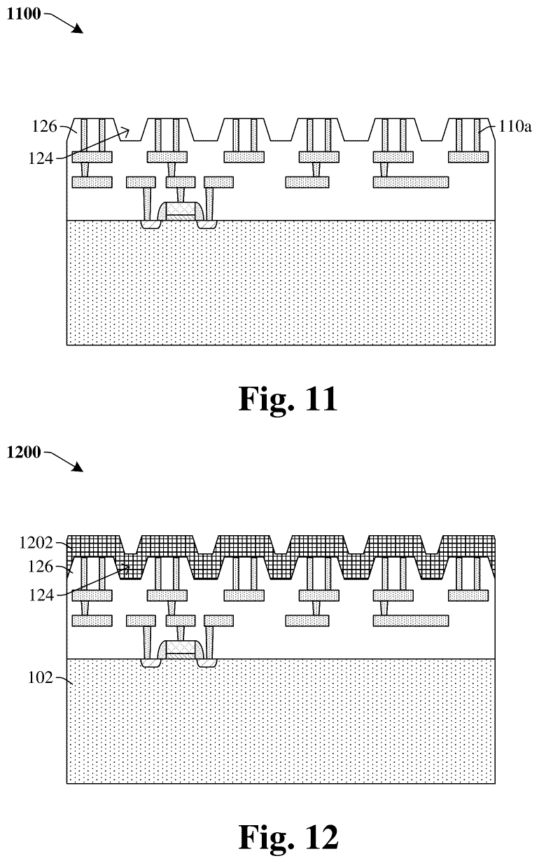

As shown in the cross-sectional view 1100 of FIG. 11, the RDL (see 202 of FIG. 2A) and the plurality of metal pads (see 204 of FIG. 2B) are removed. In some embodiments, the removal is performed using a combination of etching (e.g., dry or wet etching) and planarization processes (e.g., chemical mechanical planarization (CMP)). The removal process results in the uppermost vias 110a being exposed and the protrusions 126 and grooves 124 remaining on the uppermost surface of the interlayer dielectric 114.

As shown in the cross-sectional view 1200 of FIG. 12, a second conformal metal layer 1202 is formed over the uppermost surface of the interlayer dielectric 114. In some embodiments, the second conformal metal layer 1202 is or comprises aluminum (Al), gold (Au), titanium (Ti), ruthenium (Ru), iridium (Ir), rhodium (Rh), molybdenum (Mo), the like, or a combination thereof. The second conformal metal layer 1202 conforms to the protrusions 126 and grooves 124 on the uppermost surface of the interlayer dielectric 114, resulting in the second conformal metal layer 1202 having multiple upper surfaces of varying heights above the substrate 102. In some embodiments, the second conformal metal layer 1202 is formed using a deposition process such as PVD, ALD, CVD, or the like.

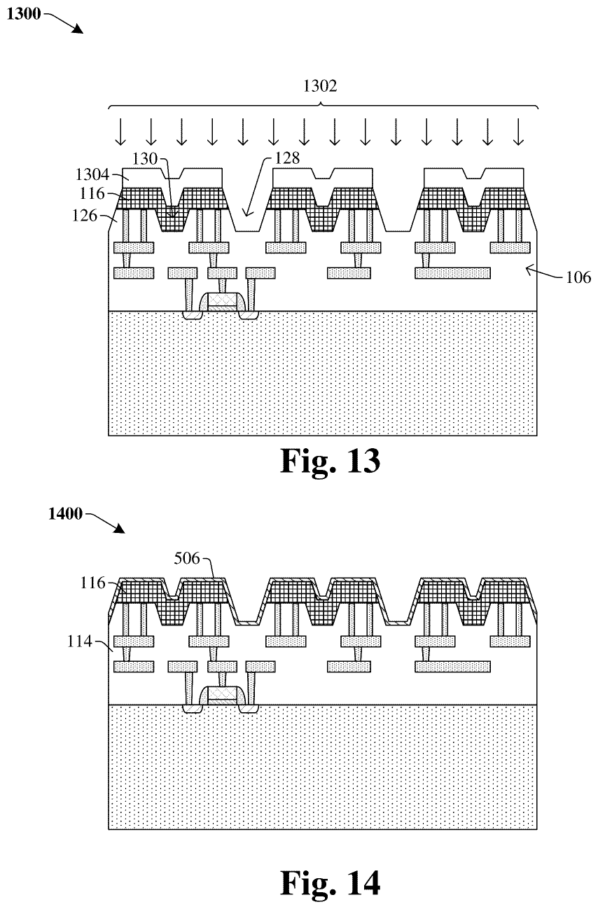

As shown in the cross-sectional view 1300 of FIG. 13, a second mask 1304 is formed over the interconnect structure 106 and subsequently patterned. In some embodiments, the second mask 1304 comprises a photoresist and is patterned using photolithography. After the second mask 1304 is patterned, the second conformal metal layer (see 1202 of FIG. 12) is patterned to form the plurality of conductive pads 116. The pattern of the plurality of conductive pads 116 configured to couple uppermost vias 110a together is based on the layout of the integrated circuit.

In some embodiments, the patterning is performed using a dry etching process 1302. The dry etching process 1302 removes portions of the second conformal metal layer (see 1202 of FIG. 12) that are not covered by the second mask 1304. In some embodiments, the interlayer dielectric 114 is partially etched away by the dry etching process 1302, resulting in the extension of the grooves 124 further into the interlayer dielectric 114, and resulting in a first portion 128 of grooves 124 having an upper surface with a height above the substrate 102 less than a height of the upper surface at the bottom of a second portion 130 of grooves 124 beneath the conductive pads 116. The second mask 1304 is subsequently removed.

As shown in the cross-sectional view 1400 of FIG. 14, the third barrier layer 506 is formed over the plurality of conductive pads 116 and the interlayer dielectric 114. In some embodiments, the third barrier layer 506 is or comprises aluminum oxide (Al₂O₃), hafnium oxide (HfO₂), titanium oxide (TiO₂), silicon nitride (Si₃N₄), titanium nitride (TiN), another similar material, or a combination thereof. In some embodiments, the third barrier layer 506 is formed using a deposition process such as PVD, ALD, CVD, or the like.

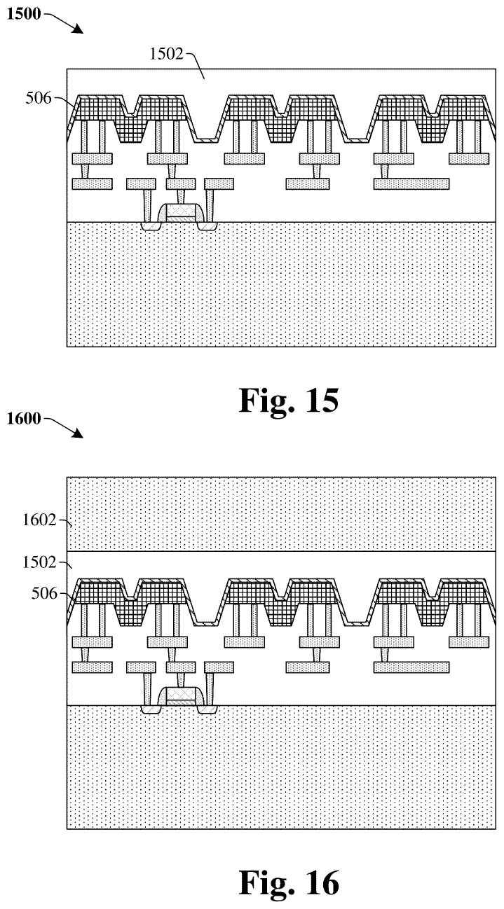

As shown in the cross-sectional view 1500 of FIG. 15, an insulative layer 1502 if formed over the third barrier layer 506. In some embodiments, the insulative layer 1502 is or comprises an insulative material such as silicon oxide (SiO₂), silicon nitride (Si₃N₄), or the like. In some embodiments, the insulative layer 1502 if formed using a deposition process such as PVD, ALD, CVD, or the like, and then is subsequently planarized using CMP or the like.

As shown in the cross-sectional view 1600 of FIG. 16, a first carrier wafer 1602 is bonded to the insulative layer 1502. In some embodiments, the first carrier wafer 1602 is or comprises silicon, silicon germanium (SiGe), or the like, or comprises a silicon on insulator (SOI) substrate. In some embodiments, the first carrier wafer 1602 is bonded to the insulative layer 1502 using direct bonding.

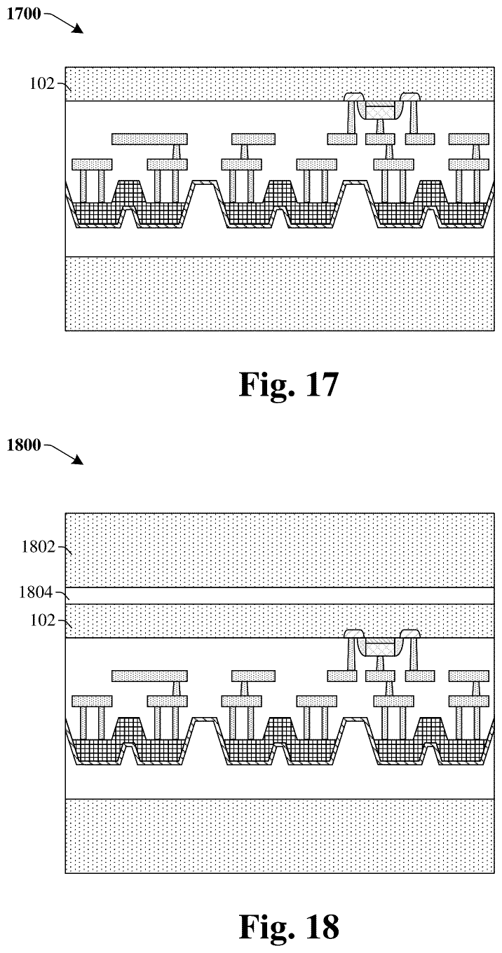

As shown in the ross-sectional view 1700 of FIG. 17, a portion of the substrate 102 is removed to reach a specified thickness. In some embodiments, the portion of the substrate 102 is removed using a grinding process. In some embodiments, the specified thickness is approximately between 3 and 10 micrometers, between 2 and 7 micrometers, between 4 and 13 micrometers, or within another, similar range.

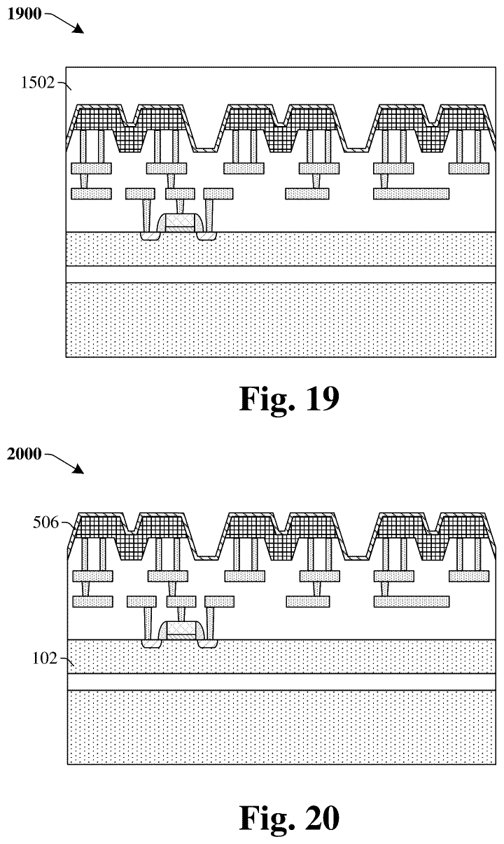

As shown in the ross-sectional view 1800 of FIG. 18, a second carrier wafer 1802 is bonded to the substrate 102. In some embodiments, the second carrier wafer 1802 is or comprises silicon, silicon germanium (SiGe), or the like, or comprises a silicon on insulator (SOI) substrate. The second carrier wafer 1802 is bonded to the substrate 102 by an adhesive layer 1804. The adhesive layer 1804 and second carrier wafer 1802 are configured to hold the semiconductor dies (see 140 of FIG. 2A) through the method steps shown in FIGS. 19 and 20.

As shown in the cross-sectional view 1900 of FIG. 19, the first carrier wafer (see 1602 of FIG. 16) is removed from the insulative layer 1502. In some embodiments, the first carrier wafer (see 1602 of FIG. 16) is removed using a grinding or thinning process. As shown in the cross-sectional view 2000 of FIG. 20, in some embodiments, the insulative layer (see 1502 of FIG. 19) is removed from the substrate 102. Removal of the insulative layer (see 1502 of FIG. 19) exposes the third barrier layer 506. In some embodiments, a portion of the insulative layer (see 1502 of FIG. 19) is removed during the same grinding or thinning process that removed the first carrier wafer (see 1602 of FIG. 16). In some embodiments, portions of the insulative layer (see 1502 of FIG. 19) are removed using an etching process that is selective for the material of the insulative layer (see 1502 of FIG. 19). In some embodiments, the insulative layer (see 1502 of FIG. 19) is not removed, and instead functions as a dielectric to surround a via level to be formed hereafter.

As shown in the cross-sectional view 2100 of FIG. 21, openings are etched into the third barrier layer 506, and the second interconnect structure 402 is formed on the plurality of conductive pads 116. The micro-LEDs 404 are subsequently formed on the second interconnect structure 402. In some embodiments, the plurality of semiconductor dies 140 are diced before the formation of the second interconnect structure 402 and the micro-LEDs 404, such that the semiconductor dies 140 are separated from one another. In some embodiments, the plurality of semiconductor dies 140 are diced using a selective etching process. The semiconductor dies 140 are then transferred (e.g., using a mass transferring technology) off of the adhesive layer (see 1804 of FIG. 18) to then have the second interconnect structure 402 and the micro-LEDs 404 be formed. In some embodiments, a portion of the semiconductor dies 140 that failed the electrical test (or were electrically coupled to a semiconductor die 140 that failed the electrical test by the RDL (see 202 of FIG. 2C) do not have the micro-LEDs be formed upon the plurality of conductive pads 116. In other embodiments, the portion of the semiconductor dies 140 that failed the electrical test do have the micro-LEDs 404 formed on the plurality of conductive pads 116 before the failed dies are discarded. In some embodiments, the plurality of micro-LEDs 404 are omitted, and other suitable light emitting devices are formed over the plurality of conductive pads 116 instead.

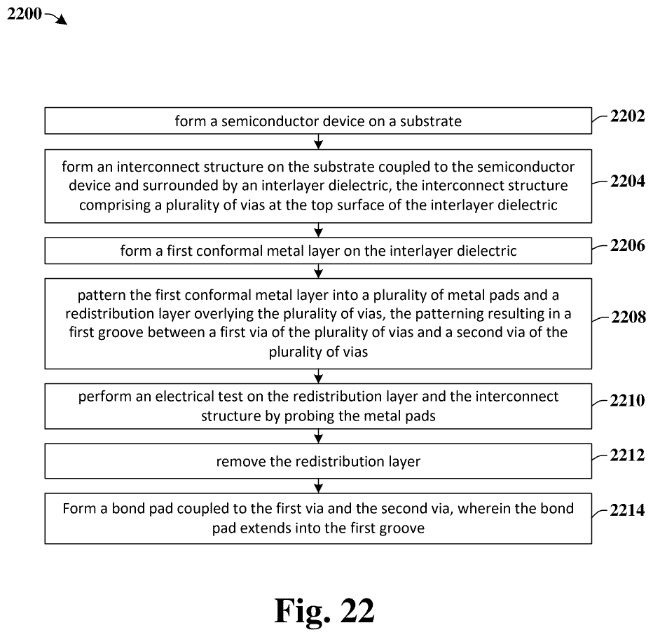

FIG. 22 illustrates a flowchart 2200 of some embodiments of a method of forming an integrated device utilizing the known-good-die (KGD) approach. Although this method and other methods illustrated and/or described herein are illustrated as a series of acts or events, it will be appreciated that the present disclosure is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At 2202, a semiconductor device is formed on a substrate. An example of a drawing illustrating this step can be found, for example, in FIG. 7.

At 2204, an interconnect structure is formed on the substrate coupled to the semiconductor device and surrounded by an interlayer dielectric, the interconnect structure comprising a plurality of vias at the top surface of the interlayer dielectric. An example of a drawing illustrating this step can be found, for example, in FIG. 8.

At 2140, a first conformal metal layer is formed on the interlayer dielectric. An example of a drawing illustrating this step can be found, for example, in FIG. 9.

At 2208, the first conformal metal layer is patterned into a plurality of metal pads and a redistribution layer overlying the plurality of vias, the patterning resulting in a first groove between a first via of the plurality of vias and a second via of the plurality of vias. An example of a drawing illustrating this step can be found, for example, in FIG. 10A.

At 2210, an electrical test is performed on the redistribution layer and the interconnect structure by probing the metal pads. An example of a drawing illustrating this step can be found, for example, in FIG. 10B.

At 2212, the redistribution layer is removed. An example of a drawing illustrating this step can be found, for example, in FIG. 11.

At 2214, a conductive pad is formed coupled to the first via and the second via, wherein the conductive pad extends into the first groove. An example of a drawing illustrating this step can be found, for example, in FIGS. 12-13.

Some embodiments relate to an integrated circuit, including: a substrate comprising a top surface; a semiconductor device on the substrate; an interconnect structure overlying the substrate and coupled to the semiconductor device; a first conductive pad coupled to the interconnect structure, wherein the first conductive pad has a first upper surface at a first height above the top surface of the substrate, and a second upper surface a second height above the top surface of the substrate, wherein the first height is greater than the second height.

Other embodiments relate to an integrated device, including: a substrate; a plurality of semiconductor devices over the substrate; an interconnect structure coupled to the plurality of semiconductor devices; an interlayer dielectric surrounding the interconnect structure and comprising a first surface at a first height above the substrate, a second surface at a second height above the substrate, and a third surface a third height above a substrate, the second height being less than the first height and the third height; a first conductive pad including a lower surface conforming to the first surface, the second surface, and the third surface of the interlayer dielectric and coupled to the interconnect structure through the first surface of the interlayer dielectric.

Yet other embodiments relate to a method of forming an integrated device, the method including: forming a semiconductor device on a substrate; forming an interconnect structure on the substrate coupled to the semiconductor device and surrounded by an interlayer dielectric, the interconnect structure including a plurality of uppermost vias at the top surface of the interlayer dielectric; forming a first conformal metal layer on the interlayer dielectric; patterning the first conformal metal layer into a plurality of metal pads and a redistribution layer overlying the plurality of uppermost vias, the patterning resulting in a first groove between a first via of the plurality of uppermost vias and a second via of the plurality of uppermost vias; performing an electrical test on the redistribution layer and the interconnect structure by probing the metal pads; removing the redistribution layer; forming a conductive pad coupled to the first via and the second via, wherein the conductive pad extends into the first groove.

It will be appreciated that in this written description, as well as in the claims below, the terms “first”, “second”, “second”, “third” etc. are merely generic identifiers used for ease of description to distinguish between different elements of a figure or a series of figures. In and of themselves, these terms do not imply any temporal ordering or structural proximity for these elements, and are not intended to be descriptive of corresponding elements in different illustrated embodiments and/or un-illustrated embodiments. For example, “a first dielectric layer” described in connection with a first figure may not necessarily correspond to a “first dielectric layer” described in connection with another figure, and may not necessarily correspond to a “first dielectric layer” in an un-illustrated embodiment.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit, comprising:
a substrate comprising a top surface;
a semiconductor device on the substrate;
an interconnect structure overlying the substrate and coupled to the semiconductor device; and
a first conductive pad coupled to the interconnect structure, wherein the first conductive pad has a first upper surface at a first height above the top surface of the substrate, and a second upper surface a second height above the top surface of the substrate, wherein the first height is greater than the second height.

2. The integrated circuit of claim 1, wherein the first conductive pad has a third upper surface with a third height that is greater than the second height, and wherein the second upper surface is between the first upper surface and the third upper surface.

3. The integrated circuit of claim 2, wherein the second upper surface extends from a first sidewall of the first conductive pad to a second sidewall of the first conductive pad.

4. The integrated circuit of claim 2, wherein the first conductive pad is coupled to the interconnect structure at a first lower surface directly beneath the first upper surface and a second lower surface directly beneath the third upper surface.

5. The integrated circuit of claim 1, wherein the first conductive pad is coupled to the interconnect structure by uppermost vias, and wherein a bottom surface of the first conductive pad extends beneath upper surfaces of the uppermost vias.

6. The integrated circuit of claim 1, further comprising a second conductive pad coupled to the interconnect structure, wherein the second conductive pad comprises a third upper surface at the first height above the top surface of the substrate, and a fourth upper surface at the second height above the top surface of the substrate.

7. A integrated device, comprising:
a substrate;
a plurality of semiconductor devices over the substrate;
an interconnect structure coupled to the plurality of semiconductor devices;
an interlayer dielectric surrounding the interconnect structure and comprising a first surface at a first height above the substrate, a second surface at a second height above the substrate, and a third surface at a third height above the substrate, the second height being less than the first height and the third height; and
a first conductive pad comprising a lower surface conforming to the first surface, the second surface, and the third surface of the interlayer dielectric and coupled to the interconnect structure through the first surface of the interlayer dielectric.

8. The integrated device of claim 7, further comprising a second conductive pad on the interlayer dielectric, wherein an groove in the interlayer dielectric spaces the first conductive pad from the second conductive pad, and wherein the interlayer dielectric comprises a fourth surface at a bottom of the groove at a fourth height above the substrate, the fourth height being not higher than the second height.

9. The integrated device of claim 7, wherein the first conductive pad has a first upper surface directly over the first surface of the interlayer dielectric, a second upper surface directly over the second surface of the interlayer dielectric, and a third upper surface directly over the third surface of the interlayer dielectric, and wherein the second upper surface is beneath the first upper surface and the third upper surface.

10. The integrated device of claim 7, wherein the first conductive pad is coupled to the interconnect structure through the third surface of the interlayer dielectric.

11. The integrated device of claim 10, wherein the first conductive pad is coupled to the interconnect structure through the first surface using a first plurality of vias and wherein the first conductive pad is coupled to the interconnect structure through the third surface using a second plurality of vias.

12. The integrated device of claim 7, wherein the second surface extend between the first surface and the third surface and extends to an outer sidewall of the interlayer dielectric.

13. A method of forming an integrated device, the method comprising:
forming a semiconductor device on a substrate;
forming an interconnect structure on the substrate coupled to the semiconductor device and surrounded by an interlayer dielectric, the interconnect structure comprising a plurality of uppermost vias at a top surface of the interlayer dielectric;
forming a first conformal metal layer on the interlayer dielectric;
patterning the first conformal metal layer into a plurality of metal pads and a redistribution layer overlying the plurality of uppermost vias, the patterning resulting in a first groove between a first via of the plurality of uppermost vias and a second via of the plurality of uppermost vias;
performing an electrical test on the redistribution layer and the interconnect structure by probing the metal pads;
removing the redistribution layer; and
forming a conductive pad coupled to the first via and the second via, wherein the conductive pad extends into the first groove.

14. The method of claim 13, further comprising dicing the substrate and the interconnect structure to separate a plurality of semiconductor dies from the integrated device.

15. The method of claim 14, wherein forming the conductive pad further comprises:
forming a second conformal metal layer over the plurality of uppermost vias;
forming and patterning a mask over the second conformal metal layer, wherein the mask is patterned to expose portions of a conformal metal layer within a second groove formed during the patterning of the first conformal metal layer; and
patterning the conformal metal layer to leave the conductive pad on the interlayer dielectric.

16. The method of claim 13, wherein after the conductive pad is formed, the first groove extends past outer sidewalls of the conductive pad.

17. The method of claim 13, further comprising:
forming a barrier layer over the conductive pad and the interlayer dielectric;
forming an insulative layer over the barrier layer;
bonding a first carrier wafer to the insulative layer;
removing a portion of the substrate to expose a lower surface of the substrate;
bonding a second carrier wafer to the lower surface of the substrate; and
removing the first carrier wafer, the insulative layer, and the barrier layer, exposing the conductive pad and the interlayer dielectric.

18. The method of claim 17, wherein the second carrier wafer is bonded to the lower surface of the substrate using an adhesive.

19. The method of claim 17, wherein after the portion of the substrate is removed, the substrate has a thickness between 3 and 10 micrometers.

20. The method of claim 13, wherein the plurality of uppermost vias of the interconnect structure are formed using a single damascene process.
